(19) United States
(12) Patent Application Publication
(10) Pub. No.: US 2016/0372413 A1
(43) Pub. Date: Dec. 22, 2016

(54) UNIQUE BI-LAYER ETCH STOP TO PROTECT CONDUCTIVE STRUCTURES DURING A METAL HARD MASK REMOVAL PROCESS AND METHODS OF USING SAME

(71) Applicant: GLOBALFOUNDRIES Inc., Grand Cayman (KY)

(72) Inventors: Anbu Selvam Mahalingam, Malta, NY (US); Ashwini Chandrashekar, Clifton Park, NY (US); Craig Child, Gansevoort, NY (US)

(21) Appl. No.: 14/741,636

(22) Filed: Jun. 17, 2015

(51) Int. Cl. H01L 23/528; H01L 21/311; H01L 23/522; H01L 21/02; H01L 23/532; H01L 21/3205; H01L 21/768

(52) U.S. Cl. CPC H01L 23/528; H01L 21/32051; H01L 21/31144; H01L 21/76822; H01L 21/76877; H01L 21/02164; H01L 21/02167; H01L 21/0217; H01L 21/0214; H01L 23/53228; H01L 23/53266; H01L 23/5226; H01L 23/53295

(57) ABSTRACT

One method includes, among other things, forming a bi-layer etch stop layer above a conductive contact comprised of titanium nitride, the bi-layer etch stop layer consisting of an upper second layer that is made of aluminum nitride, forming a patterned etch mask comprised of a layer of titanium nitride above a second layer of insulating material, with the bi-layer etch stop layer in position above the conductive contact, performing an etching process through the patterned etch mask to define a cavity in the second layer of insulating material, performing a second etching process to remove at least the layer of titanium nitride of the patterned etch mask, forming an opening in the bi-layer etch stop layer so as to thereby expose a portion of the conductive contact and forming a conductive structure in the cavity that is conductively coupled to the exposed portion of the conductive contact.

### BACKGROUND OF THE INVENTION

### 1. Field of the Invention

Generally, the present disclosure relates to the manufacture of semiconductor devices, and, more specifically, to a unique bi-layer etch stop to protect conductive structures during a metal hard mask removal process and methods of using same.

### 2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned above the channel region and a conductive gate electrode is positioned above the gate insulation layer. By applying an appropriate voltage to the gate electrode, the channel region becomes conductive and current is allowed to flow from the source region to the drain region.

To improve the operating speed of FETs, and to increase the density of FETs on an integrated circuit device, device designers have greatly reduced the physical size of FETs over the years, particularly the channel length of transistor devices. As a result of the reduced dimensions of the transistor devices, the operating speed of the circuit components has been increased with every new device generation, and the “packing density,” i.e., the number of transistor devices per unit area, in such products has also increased during that time. Such improvements in the performance of transistor devices has reached the point where one limiting factor relating to the operating speed of the final integrated circuit product is no longer the individual transistor element but the electrical performance of the complex wiring system that is formed above the device level where the actual semiconductor-based circuit elements, such as transistors, are formed in and above the semiconductor substrate.

Typically, due to the large number of circuit elements and the required complex layout of modern integrated circuits, the electrical connections or “wiring arrangement” for the individual circuit elements cannot be established within the same device level on which the circuit elements are manufactured. Accordingly, the various electrical connections that constitute the overall wiring pattern for the integrated circuit product are formed in one or more additional stacked so-called “metallization layers” that are formed above the device level of the product. These metallization layers are typically comprised of layers of insulating material with conductive metal lines or conductive vias formed in the layers of material. Generally, the conductive lines provide the intra-level electrical connections, while the conductive vias provide the inter-level connections or vertical connections between different levels. These conductive lines and conductive vias may be comprised of a variety of different materials, e.g., copper, with appropriate barrier layers, etc. The first metallization layer in an integrated circuit product is typically referred to as the “M1” layer, while the conductive vias that are used to establish electrical connection between the M1 layer and lower level conductive structures (explained more fully below) are typically referred to as “V0” vias. The conductive lines and conductive vias in these metallization layers are typically comprised of copper, and they are formed in layers of insulating material using known damascene or dual-damascene techniques. Additional metallization layers are formed above the M1 layer, e.g., M2/V1, M3/V2, etc. Within the industry, conductive structures below the V0 level are generally considered to be “device-level” contacts or simply “contacts,” as they contact the “device” (e.g., a transistor) that is formed in the silicon substrate.

FIG. 1A is a cross-sectional view that simplistically depicts an illustrative integrated circuit product 10 comprised of a plurality of transistor devices 15 formed in and above a semiconductor substrate 12. A schematically depicted isolation region 13 has also been formed in the substrate 12. In the depicted example, the transistor devices 15 are comprised of an illustrative gate structure, i.e., a gate insulation layer 16 and a gate electrode 18, a gate cap layer 20, a sidewall spacer 22 and simplistically depicted source/drain regions 24. At the point of fabrication depicted in FIG. 1A, layers of insulating material 17A, 17B, i.e., interlayer dielectric materials, have been formed above the product 10. Other layers of material, such as etch stop layers and the like, are not depicted in FIG. 1A. Also depicted are illustrative source/drain contact structures 28 which include a combination of a so-called “trench silicide” (TS) region 28A and a metal region 28B (such as tungsten). In the depicted process flow, the upper surface of the source/drain contact structures 28 is approximately planar with the upper surface of the gate cap layers 20. Also depicted in FIG. 1A are a plurality of so-called “CA contact” structures 32 and an illustrative gate contact structure 31, which is sometimes referred to as a “CB contact” structure. The CA contact structures 32 and the CB contact structure 31 are formed to provide electrical connection between the underlying devices and the V0 via level. The CA contact structures 32 are formed to provide electrical contact to the source/drain contact structures 28, while the CB contact 31 is formed so as to contact a portion of the gate electrode 18 of one of the transistors 15. In a plan view (not shown), the CB contact 31 is positioned vertically above the isolation region 13, i.e., the CB contact 31 is not positioned above the active region defined in the substrate 12. The CA contact structures 32 may be in the form of discrete contact elements, i.e., one or more individual contact plugs having a generally square-like or cylindrical shape, that are formed in an interlayer dielectric material, as shown in FIG. 1A. In other applications (not shown in FIG. 1A), the CA contact structures 32 may also be a line-type feature that contacts underlying line-type features, e.g., the source/drain contact structures 28 that contacts the source/drain region 24 and typically extends across the entire active region on the source/drain region 24. Typically, the CB contact 31 is in the form of a round or square plug.

Also depicted in FIG. 1A is the first metallization layer—the so-called M1 layer—of the multi-level metallization system for the product 10 that is formed in a layer of insulating material 34, e.g., a low-k insulating material. A plurality of conductive vias—so-called V0 vias 40—are provided to establish electrical connection between the device-level contacts—CA contacts 32 and the CB contact 31—and the M1 layer. The M1 layer typically includes a plurality of metal lines 38 that are routed as needed across the product 10.

One problem that may be encountered when forming the V0 via to the underlying device level contacts will be discussed with reference FIGS. 1B-1C, which depict one illustrative prior art method of forming conductive structures to the contact level of an integrated circuit product using a damascene process. FIG. 1B depicts an integrated circuit product 50 comprised of an illustrative conductive device level contact 52 formed in a layer of insulating material 54. As noted above, the device level contact 52 is typically conductively coupled to a region or portion of a semiconductor device (not shown in FIG. 1B), such as the gate electrode and/or the source/drain regions of a transistor device. In the depicted example, the device level contact 52 is comprised of one or more barrier layers or liners 52A, e.g., titanium/titanium nitride, and a bulk conductive material 52B, e.g., tungsten. An etch stop layer 56 is formed above the layer of insulating material 54. The layers 54, 56 and the device level contact 52 may all be considered to be part of the contact level layer 55 of the integrated circuit product 50.

Electrical connections have to be made to the device level contact 52 for the product 50 to operate. Thus, a metallization layer 57 is formed above the contact level layer 55. In the depicted example, formation of the metallization layer 57 involves the formation of the first conductive via (V0) and an illustrative metal line of the first metallization layer (M1). As noted above, the product 50 will typically comprise several metallization layers, e.g., multiple layers of conductive vias and conductive lines. The M1 metallization layer is typically the first major “wiring” layer that is formed on the product 50. Formation of the V0 and M1 conductive structures involves formation of a layer of insulating material 58 and an etch mask 59 comprised of first and second layers of material 60, 62. In one example, the layers of insulating materials 54, 58 may be layers of so-called low-k (k value less than about 3.3) insulating material, the etch stop layer 56 may be a layer of silicon nitride, NBlok, etc., the layer 60 may be a TEOS-based layer of silicon dioxide, and the layer 62 may be a hard mask made of a metal, such as titanium nitride. The thickness of these various layers of material may vary depending upon the particular application.

FIG. 1B depicts the product 50 after several process operations were performed. First, using known photolithography and etching techniques, a patterned photoresist mask (not shown) was formed above the product 50 and the mask layer 59 was patterned as depicted. Thereafter, the photoresist mask was removed and one or more etching processes were performed through the patterned mask layer 59 to form the depicted via openings 64 through the layers 58, 56 so as to expose the underlying device level contact 52.

After the openings 64 are formed as depicted in FIG. 1 B, the titanium nitride hard mask layer 62 is removed. FIG. 1C depicts the product 50 after another etching process, such as a wet etching process using, for example, EKC, was performed to remove the titanium nitride hard mask layer 62. Unfortunately, during this etching process to remove the titanium nitride, portions of the barrier layer 52A that are made of titanium nitride and titanium are also attacked and consumed, as reflected by the loss of the material of the barrier layer 52A within the enclosed dashed lines 63. EKC can also attack tungsten material in the underlying device level contact 52, but loss of the tungsten material is not depicted in the drawings. Loss of such conductive materials, e.g., the titanium nitride material in the barrier layer 52A, can result in problems such as undesirable migration of materials from the bulk conductive material 52B into the insulating layer 54 and the creation of undesirable voids when subsequently formed conductive structures are formed above the damaged regions 63.

The present disclosure is directed to a unique bi-layer etch stop for protecting conductive structures during a metal hard mask removal process and methods of using same that will solve the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a unique bi-layer etch stop to protect conductive structures during a metal hard mask removal process and methods of using same. One illustrative method disclosed herein includes, among other things, forming a conductive contact comprised of titanium nitride in a first layer of insulating material, forming a bi-layer etch stop layer above the conductive contact, the bi-layer etch stop layer consisting of a first layer and a second layer positioned above the first layer, the second layer comprising aluminum nitride, forming at least one second layer of insulating material above the bi-layer etch stop layer and forming a patterned etch mask comprised of a layer of titanium nitride above the second layer of insulating material. In this example, the method also includes, with the bi-layer etch stop layer in position above the conductive contact, performing at least one first etching process through the patterned etch mask to define a cavity in the second layer of insulating material, and performing at least one second etching process to remove at least the layer of titanium nitride of the patterned etch mask, performing at least one third etching process to define an opening in the bi-layer etch stop layer and thereby expose a portion of the conductive contact and forming a conductive structure in the cavity that is conductively coupled to the exposed portion of the conductive contact.

One illustrative device disclosed herein includes, among other things, a conductive contact comprised of titanium nitride positioned in at least one first layer of insulating material, a bi-layer etch stop layer consisting of a first layer and a second layer positioned above the conductive contact, wherein the first layer is positioned on and in contact with an upper surface of the first layer of insulating material and the second layer is a layer of aluminum nitride that is positioned on and in contact with an upper surface of the first layer of the bi-layer etch stop layer, at least one second layer of insulating material positioned above the second layer of the bi-layer etch stop layer, at least one opening that extends through the at least one second layer of insulating material and the bi-layer etch stop layer and exposes a portion of the conductive contact and a conductive structure positioned in the at least one opening that is conductively coupled to the exposed portion of the conductive contact.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1C depict one illustrative prior art method of forming conductive structures to the contact level of an integrated circuit product using a damascene process; and

FIGS. 2A-2H depict one illustrative method disclosed herein of forming a unique bi-layer etch stop to protect conductive structures during a metal hard mask removal process and the resulting integrated circuit product.

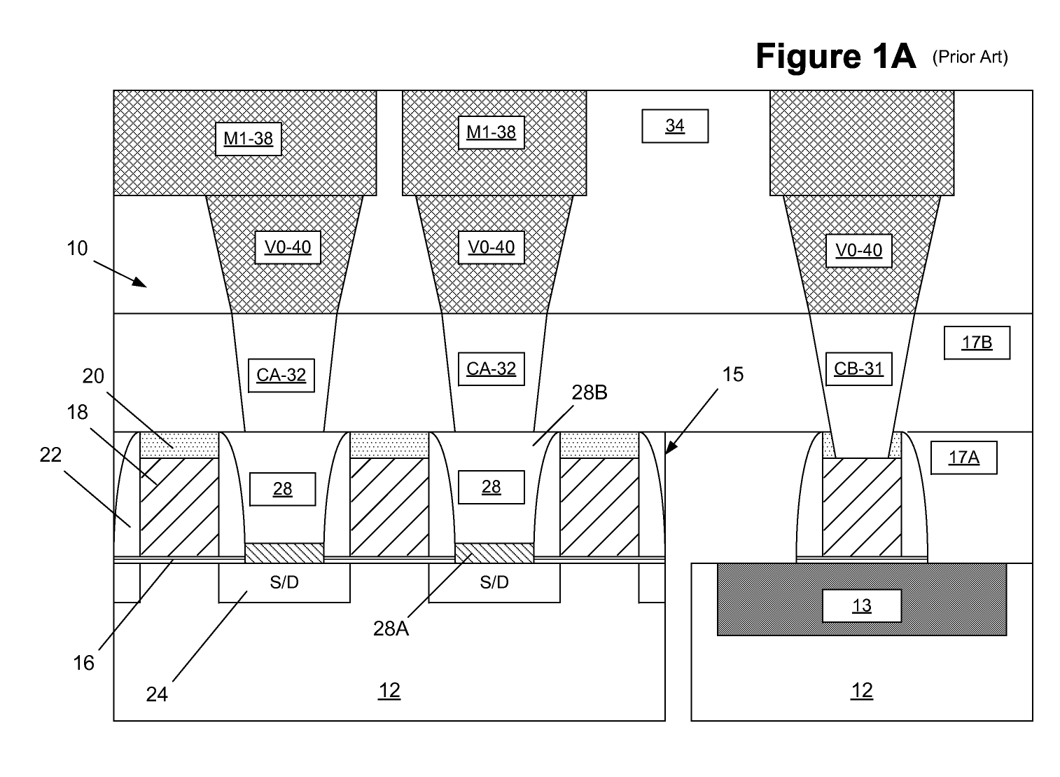

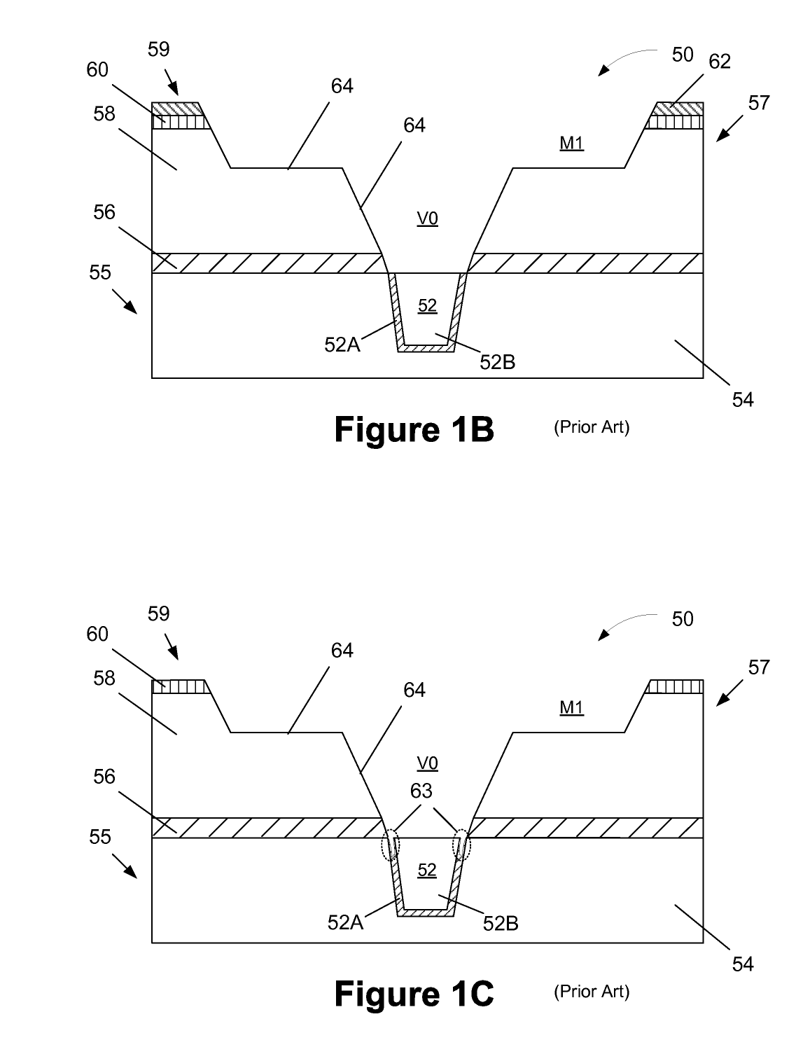

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming conductive structures, such as conductive contacts and conductive lines/vias, using a sacrificial material during the process of removing a metal hard mask layer used in forming such conductive structures. As will be readily apparent to those skilled in the art upon a complete reading of the present application, the methods disclosed herein may be employed when forming conductive structures that contact a variety of different semiconductor devices, e.g., transistors, memory cells, resistors, etc., and may be employed when forming conductive structures for a variety of different integrated circuit products, including, but not limited to, ASIC's, logic devices, memory devices, etc. With reference to the attached drawings, various illustrative embodiments of the methods disclosed herein will now be described in more detail.

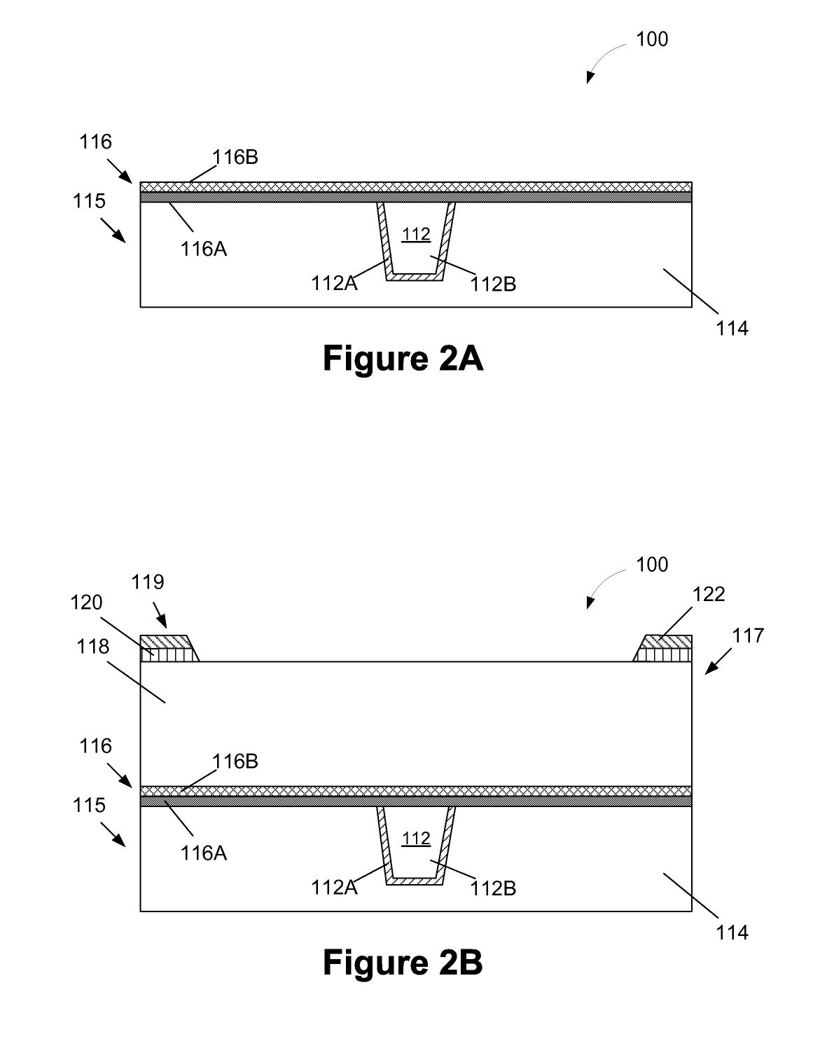

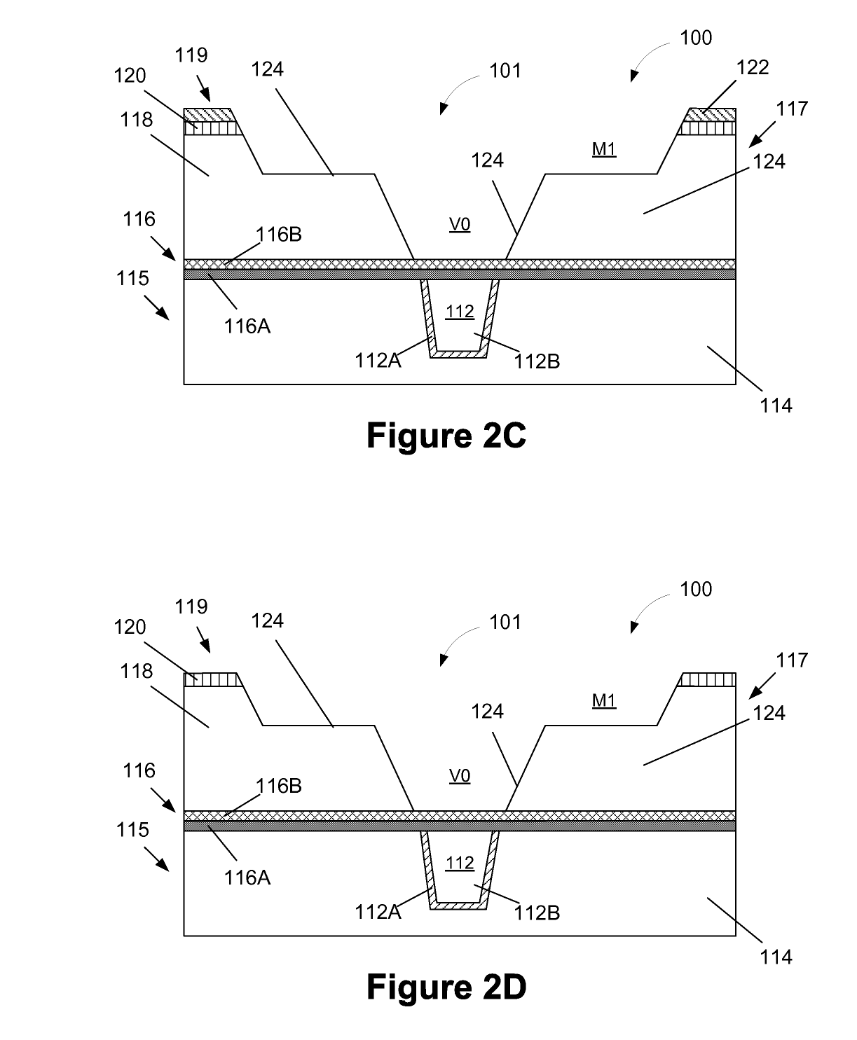

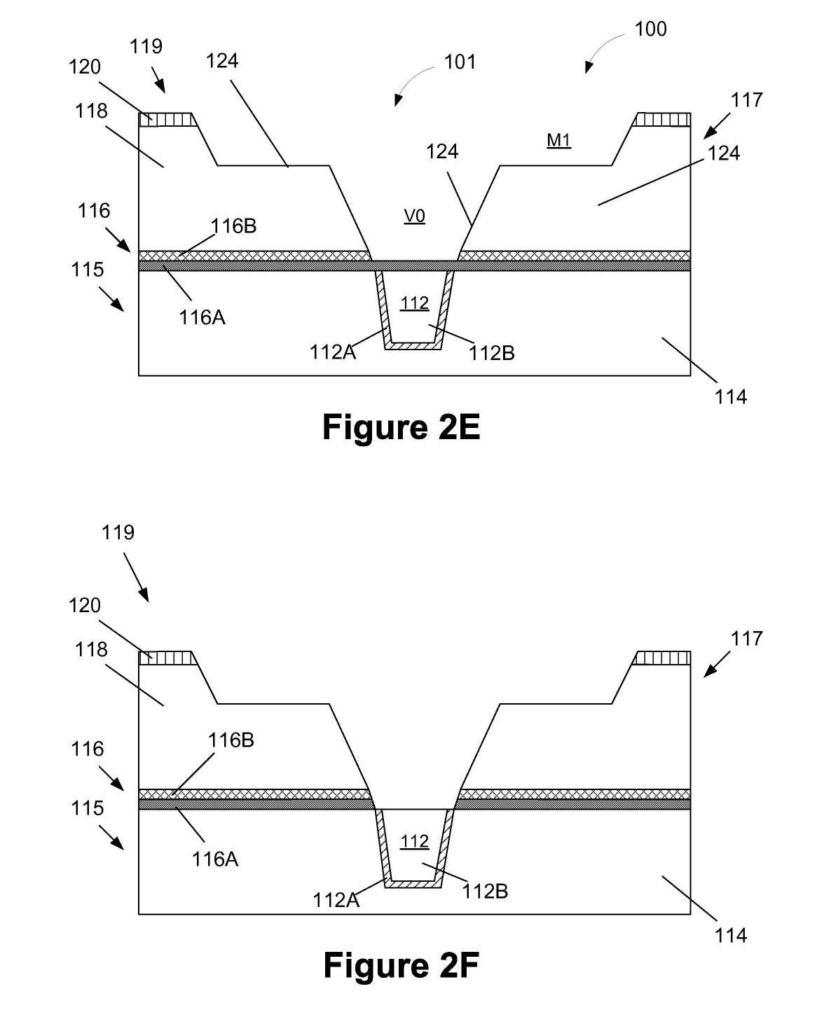

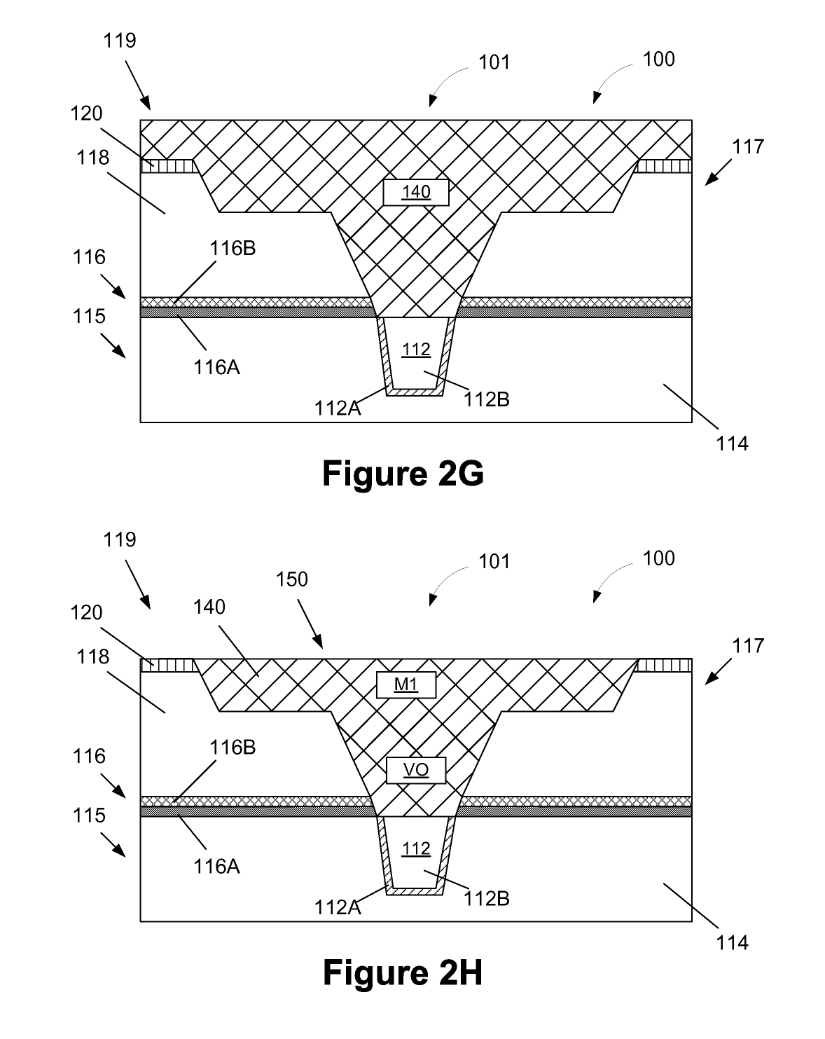

FIGS. 2A-2H depict one illustrative method disclosed herein of forming a unique bi-layer etch stop to protect conductive structures during a metal hard mask removal process and the resulting integrated circuit product. FIG. 2A is a simplified view of an illustrative integrated circuit (IC) product 100 at an early stage of manufacturing that is formed above a semiconductor substrate (not shown). The substrate may have a variety of configurations, such as a bulk substrate configuration, an SOI (silicon-on-insulator) configuration, and it may be made of materials other than silicon. Thus, the terms “substrate” or “semiconductor substrate” should be understood to cover all semiconducting materials and all forms of such materials. The IC product 100 may be any type of integrated circuit product that employs any type of a titanium-containing conductive structure, such as a device-level contact commonly found on integrated circuit devices. In the examples depicted herein, the device-level conductive structures are described as having a representative barrier and/or adhesion layer. In practice, there may be one or more such barrier/adhesion layers used in a real-world product. The vias and metal lines described and discussed herein may be made of any type of conductive material, e.g., a metal or a metal alloy, such as copper or a copper-based material. The layers of material depicted herein may be formed by performing a variety of known processing techniques, such as a chemical vapor deposition (CVD) process, an atomic layer deposition (ALD) process, a physical vapor deposition (PVD) process, or plasma enhanced versions of such processes, electroplating, etc.

FIG. 2A depicts an IC product 100 comprised of an illustrative device-level conductive contact 112 that was formed in a layer of insulating material 114. In one example, the layer of insulating material 114 may be a layer of silicon dioxide or a layer of a so-called low-k (k value less than about 3.3) insulating material, and it may be formed to any desired thickness depending upon the particular application. Of course, in a real-world product, there will be millions of such device-level conductive contacts 112 formed in the layer of insulating material 114. The device-level conductive contact 112 is formed in the contact level 115 of the product 100, i.e., below the V0 via. Typically, the device-level conductive contact 112 is conductively coupled to a region or portion of a semiconductor device (not shown), such as the gate electrode and/or the source/drain regions of a transistor device. In the depicted example, the device-level conductive contact 112 is comprised of titanium nitride, e.g., one or more barrier layers or liners 112A, e.g., titanium nitride, and a bulk conductive material 112B, e.g., tungsten. In one particular example, the device-level conductive contact 112 is comprised of a dual-liner barrier layer comprised of a layer of titanium and a layer of titanium nitride wherein the bulk tungsten material is positioned in contact with the layer of titanium nitride.

Also depicted in FIG. 2A is a novel bi-layer etch stop layer 116, consisting of first and second layers 116A-B, that was formed above the layer of insulating material 114 and the device-level conductive contact 112. In one embodiment, the first layer 116A is formed on and in contact with the upper surface of the layer of insulating material 114 and on and in contact with the upper surface of the device-level conductive contact 112, while the second layer 116B is formed on and in contact with the upper surface of the first layer 116A. In one example, the first layer 116A may be comprised of nitrogen-doped silicon carbide or silicon nitride and the second layer 116B is made of aluminum nitride. The first and second layers 116A-B may be formed by performing any of a variety of known deposition processes, e.g., ALD, CVD, PVD, etc., or plasma enhanced versions of such processes. In one illustrative embodiment, the first layer 116A may have a thickness of about 6-8 nm, while the second layer 116B may have a thickness of about 2-4 nm

As noted in the background section of this application, electrical connections have to be made to the device-level conductive contact 112 for the product 100 to operate. Thus, FIG. 2B depicts the product 100 after another metallization layer 117 was formed above the contact level layer 115. In the example depicted herein, and as described more fully below, the formation of the metallization layer 117 involves the formation of the first conductive via (V0) and an illustrative metal line of the first metallization layer (M1) (not shown in FIG. 2B). The product 100 will typically comprise several metallization layers, e.g., multiple layers of conductive vias and conductive lines.

FIG. 2B depicts the product 100 after several process operations were performed. First, a layer of insulating material 118 was deposited above the bi-layer etch stop layer 116. Next, a patterned etch mask 119 comprised of first and second layers of material 120, 122 was formed above the layer of insulating material 118. The etch mask 119 may be patterned using known photolithography and etching techniques, i.e., a patterned photoresist mask (not shown) was formed above the layer of material 122 and the mask layer 119 was patterned as depicted. In one example, the layer of insulating material 118 may be a layer of so-called low-k (k value less than about 3.3) insulating material, the layer 120 may be a layer of silicon oxynitride (SiON), a TEOS-based layer of silicon dioxide, etc., and the layer 122 of the patterned etch mask is made of titanium nitride. The thickness of these layers of material may vary depending upon the particular application.

FIG. 2C depicts the product 100 after one or more etching processes were performed through the patterned etch mask layer 119 to form the depicted openings 124 through the layer of insulating material 118 and thereby expose a portion of the second layer 116B (aluminum nitride) of the bi-layer etch stop layer 116. Importantly, during this etching process, the bi-layer etch stop layer 116 remains positioned above the device-level conductive contact 112. That is, the upper aluminum nitride layer 116B of the bi-layer etch stop layer 116 serves as an effective etch stop when forming the openings 124. The shape and size of the openings 124 depicted in the attached drawings are representative in nature, as the number, size and shape of the openings 124 may vary depending upon the particular application. In some embodiments where the presently disclosed inventions may be employed, only a single opening may be formed in the layer of insulating material 118, instead of the stepped, dual openings 124 depicted in FIG. 2C. Thus, the opening(s) 124 will generically be referred to as a cavity 101 irrespective of the size or shape of the opening(s) 124 or the manner in which it is formed. A conductive structure (not shown in FIG. 2C) will eventually be formed in the cavity 101 (i.e., the openings 124) so as to provide electrical contact to the device-level conductive contact 112.

After the cavity 101 is formed, the titanium nitride hard mask layer 122 will be removed by performing an etching process. Accordingly, FIG. 2D depicts the product 100 after a wet etching process, using for example EKC, was performed to remove the titanium nitride hard mask layer 122. Importantly, during the etching process that is performed to remove the titanium nitride hard mask layer 122, the bi-layer etch stop layer 116 remains positioned above and protects the device-level conductive contact 112. That is, the upper aluminum nitride layer 116B of the bi-layer etch stop layer 116 serves as an effective etch stop when removing the titanium nitride hard mask layer 122. Accordingly, the device-level conductive contact 112, including the titanium nitride portion(s) of the device-level conductive contact 112 and tungsten, is not attacked when the titanium nitride hard mask layer 122 is removed, as was the case with prior art process flows.

The next major process operation involved defining an opening in the bi-layer etch stop layer 116 so as to expose at least a portion of the device-level conductive contact 112 so that an electrical connection to the device-level conductive contact 112 may be formed. Accordingly, FIG. 2E depicts the product 100 after an etching process was performed to pattern the second layer 116B of the bi-layer etch stop layer 116 using the first layer 116A as an etch stop layer. As depicted, this etching process exposes a portion of the first layer 116A for further processing.

FIG. 2F depicts the product 100 after an etching process was performed to pattern the first layer 116A of the bi-layer etch stop layer 116 so as to thereby expose at least a portion of the device-level conductive contact 112. Although a two step etching process is depicted for patterning the bi-layer etch stop layer 116, in at least some applications, depending upon the materials involved, the bi-layer etch stop layer 116 may be patterned using a single etching process so as to expose the device-level conductive contact 112.

At this point in the process flow described herein, traditional manufacturing operations may be performed to form one or more conductive materials in the cavity 101 so as to thereby form a conductive structure—e.g., the V0 and M1 conductive structures in the depicted example—in the cavity 101 (openings 124) that is conductively coupled to the device-level conductive contact 112. In general, the V0 and M1 structures may be formed by performing one or more deposition processes to deposit one or more layers of barrier materials (not shown) and/or seed layers (not shown), e.g., a copper seed layer, above the product 100 and in the cavity 101, and performing a bulk deposition process to overfill the opening with additional conductive material 140, such as bulk copper formed by performing an electroplating or an electroless deposition process, as shown in FIG. 2G. Thereafter, as shown in FIG. 2H, the product 100 is subjected to one or more CMP processes to remove excess materials positioned outside of the cavity 101 and thereby define the illustrative conductive structure 150—e.g., the V0 and M1 conductive structures in the depicted example—in the cavity 101 (openings 124) that is conductively coupled to the device-level conductive contact 112.

As should be clear from the foregoing, the novel methods disclosed herein provide an efficient and effective means of forming conductive structures in integrated circuit products that may solve or at least reduce some of the problems identified in the background section of this application. Note that the use of terms such as “first,” “second,” “third” or “fourth” to describe various processes in this specification and in the attached claims is only used as a shorthand reference to such steps and does not necessarily imply that such steps are performed in that ordered sequence. Of course, depending upon the exact claim language, an ordered sequence of such processes may or may not be required.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a conductive contact comprised of titanium nitride in at least one first layer of insulating material;
forming a bi-layer etch stop layer above said conductive contact, said bi-layer etch stop layer consisting of a first layer and a second layer positioned above said first layer, said second layer comprising aluminum nitride;
forming at least one second layer of insulating material above said bi-layer etch stop layer;
forming a patterned etch mask comprised of a layer of titanium nitride above said at least one second layer of insulating material;
with said bi-layer etch stop layer in position above said conductive contact, performing at least one first etching process through said patterned etch mask to define a cavity in said at least one second layer of insulating material, wherein said cavity exposes a portion of said second layer of said bi-layer etch stop layer;
with said bi-layer etch stop layer in position above said conductive contact, performing at least one second etching process to remove at least said layer of titanium nitride of said patterned etch mask;
after removing said at least said layer of titanium nitride of said patterned etch mask, performing at least one third etching process to define an opening in said bi-layer etch stop layer and thereby exposes a portion of said conductive contact; and
forming a conductive structure in said cavity that is conductively coupled to said exposed portion of said conductive contact.

2. The method of claim 1, wherein said conductive structure comprises at least one of a metal line or a conductive via.

3. The method of claim 1, wherein forming said bi-layer etch stop layer above said conductive contact comprises forming said bi-layer etch stop layer such that said first layer is formed on and in contact with an upper surface of said conductive contact and formed on and in contact with an upper surface of said first layer of insulating material.

4. The method of claim 3, wherein forming said bi-layer etch stop layer above said conductive contact comprises forming said bi-layer etch stop layer such that said second layer of said bi-layer etch stop layer is formed on and in contact with an upper surface of said first layer of said bi-layer etch stop layer.

5. The method of claim 1, wherein said at least one first layer of insulating material is comprised of silicon dioxide or an insulating material having a k value less than 3.3.

6. The method of claim 1, wherein said at least one second layer of insulating material is comprised of an insulating material having a k value less than 3.3.

7. The method of claim 1, wherein said conductive structure is comprised of copper.

8. The method of claim 1, wherein said conductive contact is comprised of a layer of titanium, a layer of titanium nitride positioned on said layer of titanium and tungsten material positioned on said layer of titanium nitride.

9. The method of claim 1, wherein performing said at least one third etching process to define said opening in said bi-layer etch stop layer comprises performing at least two third etching processes to define said opening in said bi-layer etch stop layer and thereby expose said portion of said conductive contact.

10. The method of claim 1, wherein performing said at least one third etching process to define said opening in said bi-layer etch stop layer comprises:
performing an etching process to define an opening in said second layer of said bi-layer etch stop layer so as to thereby expose a portion of said first layer of said bi-layer etch stop layer; and
performing an etching process through said opening in said second layer of said bi-layer etch stop layer to define an opening in said first layer of said bi-layer etch stop layer so as to thereby expose said portion of said conductive contact.

11. The method of claim 1, wherein said first layer of said bi-layer etch stop layer is comprised of one of nitrogen-doped silicon carbide or silicon nitride.

12. The method of claim 1, wherein said patterned etch mask further comprises a layer of silicon oxynitride or a layer of silicon dioxide.

13. The method of claim 1, wherein said first layer of said bi-layer etch stop layer has a thickness that falls within a range of about 6-8 nm and said second layer of said bi-layer etch stop layer has a thickness that falls within a range of about 2-4 nm.

14. A method, comprising:
forming a conductive contact comprised of titanium nitride in at least one first layer of insulating material;
forming a bi-layer etch stop layer consisting of a first layer and a second layer above said conductive contact, said second layer being a layer of aluminum nitride, wherein forming said bi-layer etch stop layer comprises:
depositing said first layer of said bi-layer etch stop layer on and in contact with an upper surface of said conductive contact and on and in contact with an upper surface of said first layer of insulating material; and
depositing said second layer of said bi-layer etch stop layer on and in contact with an upper surface of said first layer of said bi-layer etch stop layer;
forming at least one second layer of insulating material above said second layer of said bi-layer etch stop layer;
forming a patterned etch mask comprised of a layer of titanium nitride above said at least one second layer of insulating material;
with said bi-layer etch stop layer in position above said conductive contact, performing at least one first etching process through said patterned etch mask to define a cavity in said at least one second layer of insulating material, wherein said cavity exposes a portion of said second layer of said bi-layer etch stop layer;
with said bi-layer etch stop layer in position above said conductive contact, performing at least one second wet etching process to remove at least said layer of titanium nitride of said patterned etch mask;
after removing said at least said layer of titanium nitride of said patterned etch mask, performing a third etching process to define an opening in said second layer of said bi-layer etch stop layer so as to thereby expose a portion of said first layer of said bi-layer etch stop layer;
after performing said third etching process, performing a fourth etching process through said opening in said second layer of said bi-layer etch stop layer to define an opening in said first layer of said bi-layer etch stop layer so as to thereby expose a portion of said conductive contact; and
forming a conductive structure in said cavity that is conductively coupled to said exposed portion of said conductive contact.

15. The method of claim 14, wherein said conductive contact is comprised of a layer of titanium, a layer of titanium nitride positioned on said layer of titanium and tungsten material positioned on said layer of titanium nitride.

16. The method of claim 14, wherein said first layer of said bi-layer etch stop layer is comprised of one of nitrogen-doped silicon carbide or silicon nitride.

17. A method, comprising:
forming a conductive contact comprised of titanium nitride and tungsten in at least one first layer of insulating material;
forming a bi-layer etch stop layer consisting of a first layer and a second layer above said conductive contact, said first layer being a layer of nitrogen-doped silicon carbide having a thickness that falls within a range of about 6-8 nm, said second layer being a layer of aluminum nitride having a thickness that falls within a range of about 2-4 nm, wherein forming said bi-layer etch stop layer comprises:
depositing said first layer of said bi-layer etch stop layer on and in contact with an upper surface of said conductive contact and on and in contact with an upper surface of said first layer of insulating material; and
depositing said second layer of said bi-layer etch stop layer on and in contact with an upper surface of said first layer of said bi-layer etch stop layer;
forming at least one second layer of insulating material above said second layer of said bi-layer etch stop layer;
forming a patterned etch mask comprised of a layer of titanium nitride above said at least one second layer of insulating material;
with said bi-layer etch stop layer in position above said conductive contact, performing at least one first etching process through said patterned etch mask to define a cavity in said at least one second layer of insulating material, wherein said cavity exposes a portion of said second layer of said bi-layer etch stop layer;
with said bi-layer etch stop layer in position above said conductive contact, performing at least one second wet etching process to remove at least said layer of titanium nitride of said patterned etch mask;
after removing said at least said layer of titanium nitride of said patterned etch mask, performing a third etching process to define an opening in said second layer of said bi-layer etch stop layer so as to thereby expose a portion of said first layer of said bi-layer etch stop layer;
after performing said third etching process, performing a fourth etching process through said opening in said second layer of said bi-layer etch stop layer to define an opening in said first layer of said bi-layer etch stop layer so as to thereby expose a portion of said conductive contact; and
forming a conductive structure comprised of copper in said cavity that is conductively coupled to said exposed portion of said conductive contact.

18. A device, comprising:
a conductive contact comprised of titanium nitride positioned in at least one first layer of insulating material;
a bi-layer etch stop layer consisting of a first layer and a second layer, said bi-layer etch stop layer being positioned above said conductive contact, wherein said first layer is positioned on and in contact with an upper surface of said first layer of insulating material and said second layer is a layer of aluminum nitride that is positioned on and in contact with an upper surface of said first layer of said bi-layer etch stop layer;
at least one second layer of insulating material positioned above said second layer of said bi-layer etch stop layer;
at least one opening that extends through said at least one second layer of insulating material and said bi-layer etch stop layer and exposes a portion of said conductive contact; and
a conductive structure positioned in said at least one opening that is conductively coupled to said exposed portion of said conductive contact.

19. The device of claim 18, wherein said conductive structure comprises at least one of a metal line or a conductive via.

20. The device of claim 19, wherein said conductive structure is comprised copper.

21. The device of claim 18, wherein said conductive contact is comprised of a layer of titanium, a layer of titanium nitride positioned on said layer of titanium and tungsten material positioned on said layer of titanium nitride.

22. The device of claim 18, wherein said first layer of said bi-layer etch stop layer is comprised of one of nitrogen-doped silicon carbide or silicon nitride.

23. The device of claim 18, wherein said first layer of said bi-layer etch stop layer has a thickness that falls within a range of about 6-8 nm and said second layer of said bi-layer etch stop layer has a thickness that falls within a range of about 2-4 nm.

24. The device of claim 18, wherein said first layer is positioned on and in contact with an upper surface of said conductive contact.
